(19) United States
(12) Patent Application Publication
(10) Pub. No.: US 2020/0293704 A1
(43) Pub. Date: Sep. 17, 2020

(54) METHOD, A SYSTEM AND A COMPUTER PROGRAM PRODUCT FOR MONITORING REMOTE INFRASTRUCTURE NETWORKS

(71) Applicants: Fugro ROAMES Pty Ltd., Eight Mile Plains, QLD (AU); Fugro N.V., Leischendam (NL)

(72) Inventors: Graham VIECELLI, Greenslopes (AU); Pawel MICHALAK, Daisy Hill (AU); Daniel DAVOODIAN, South Brisbane (AU)

(73) Assignees: Fugro ROAMES Pty Ltd., Eight Mile Plains, QLD (AU); Fugro N.V., Leidschendam (NL)

(21) Appl. No.: 16/082,226

(22) PCT Filed: Mar. 7, 2017
(86) PCT No.: PCT/NL2017/050137

§ 371 Date: Sep. 4, 2018

(30) Foreign Application Priority Data
Mar. 7, 2016 (NL) 2016372

(51) Int. Cl. G06F 30/23; G06Q 10/04; G06Q 50/06

(52) U.S. Cl. CPC G06F 30/23; G06Q 50/06; G06Q 10/04

(57) ABSTRACT

The invention relates to a method for monitoring remote infrastructure networks. The method comprises the steps of collecting spatially referenced data as physical of an area containing a remote infrastructure network, identifying the remote infrastructure network in the collected physical data, and building a parametrized model of the remote infrastructure network based on the physical data and on operational data, the parametrized model including a spatially referenced model of said remote infrastructure network. Further, the method comprises the steps of storing the parametrized model and updating the parametrized model by assigning updated physical data and/or operational data associated with the remote infrastructure network to at least one parameter of the parametrized model.

The invention relates to a method for monitoring remote infrastructure networks. The monitoring method as per the present invention enables a user, not only to monitor the status of an asset, but also to be able to manage such asset more efficiently by providing an advanced parametrized model that can be easily updated and, also, provides simulating capabilities.

The state of the art in monitoring, managing and controlling remote infrastructure networks such as power transmission lines, power substations, underwater pipelines etc, offers a limited scope of solutions to identify the current status, future operability and the remaining life of a remote infrastructure network. Advanced methods are multidisciplinary with alert based outcomes providing input to Inspection Repair Maintenance (IRM) activities. Simulation aided engineering is utilised to calibrate hysteresis models capable of predicting future outcomes based on the observed behaviour and expected future conditions.

There are many existing approaches to Asset Management, however they are all a reactive process—the current state of an asset is assessed at regular intervals and compared to the expected state according to the original design premise. Changes to the operating conditions or environment require co-ordination outside the existing services provided by Asset Management as it falls in the realm of Engineering Design. In this way, the current state of the art cannot be described as an efficient, continuous and/or interactive process, and Engineering Design activities are coordinated as discontinuous campaigns with specific, finite objectives.

Generally, assets are designed to operate within an assumed set of initial, environmental and operating conditions during their assumed Useful Life, typically by designing to best estimate approximations of the assumed through life conditions. Once manufactured and installed, the actual experienced conditions may differ significantly from the original design assumptions, additionally the asset owner may wish to operate the asset outside the original design environment.

Traditionally this problem has been addressed through Inspection Repair Maintenance activities to manage unexpected environmental and operating conditions, and Fitness For Service calculations in lieu of repair, or to operate beyond the original design envelope or original design life of the asset. There is currently no solution that provides an integrated solution as an interactive and/or predictive simulation capable of providing Engineering Advice on asset response to changing environment and/or operating conditions.

It is an object of the invention to provide an integrated solution as an interactive and/or predictive simulation capable of providing Engineering Advice on asset response to changing environment and/or operating conditions. Thereto, according to an aspect of the invention, a method for monitoring remote infrastructure networks is provided, comprising the steps of collecting spatially referenced data as physical data of an area containing a remote infrastructure network; identifying the remote infrastructure network in the collected physical data; building a parametrized model of the remote infrastructure network based on the physical data and on operational data, the parametrized model including a spatially referenced model of said remote infrastructure network; storing the parametrized model, and updating the parametrized model by assigning updated physical data and/or operational data associated with the remote infrastructure network to at least one parameter of the parametrized model.

By updating the parametrized model in a process of assigning updated physical data and/or operational data associated with the remote infrastructure network to at least one parameter of the parametrized model, an integrated solution is obtained for monitoring the actual operational status of the remote infrastructure network so that interactive and/or predictive simulation is facilitated capable of responding to changing environmental and/or operational conditions.

Advantageously, a transmission step can be included for transmitting data of the parametrized model to a visualization station for providing a graphical representation of the parametrized model. Then, an operator is enabled to monitor the status of an asset in an efficient, effective and user-friendly way to support managing activities interacting with the asset, e.g. for controlling the asset, providing technical advice and/or simulating operation of the asset.

Then, a Virtual World Asset Management System can be provided through which infrastructure managers can remotely investigate and monitor the condition and performance of their network. This innovative technology is based on modeling and simulating behavior of remote infrastructure networks based on remote observation which creates a representation of the real world of such fidelity that it can be used for asset inspection, identification, condition assessment, future behavior simulation and prediction which decreases the need of frequent field visits. Here, remote infrastructure networks can be modeled with their relevant geometric, structural, mechanical, electrical, and thermal characteristics, enabling a deeper understanding of asset behavior and supporting many asset management activities. As an example, thermal and pressure information about an asset can be provided and compared with the spatially referenced data such as, for example, location-indexed infrared imaging data. By spatially referenced data it should be understood any type of data that comprises location information and this location information can be relative to another object, relative to the center of the earth (georeferenced) or any other type of location-indexed data as will be understood by a skilled person.

Mapping techniques can be combined with commoditized cloud computing, sophisticated deep learning computer algorithms and cutting-edge next generation data acquisition platforms to deliver a complete and accurate geometric virtual model of asset networks. Real time engineering advice is provided through integrated predictive simulation using calibrated hysteresis models. With an understanding of the evolving nature of assets, managers can tune their process, capital and maintenance programs as well as operational incident response to reduce operational risks and costs.

In an advantageous way, existing technology and processes are leveraged into a single, interactive environment to form a new paradigm in how assets are operated and maintained through life. An Asset is treated as a dynamic object within a parametric design space containing temporal and spatial, hypothetical, i.e. assumed, and actual data. Assumed data may include environment data, type of fluid data, pressure data etcetera. During the design of subsea pipelines, as an example, many environment variables are assumed such as seawater temperature during installation, soil friction and penetration, i.e. burial, marine growth, and process data such as temperature and pressure, particularly during first start-up. Most of these assumptions can be back-calculated once the asset has been installed and operating through the hysteresis simulation feedback process. Uncertainty in the hypothetical data space is reduced through a continuous improvement process, utilising hysteresis simulation feedback loops whereby feature subset selection is calibrated from actual, realised asset behaviour leading to increased asset value and useful life. By feeding measurement data back to the parametrized model, the modelled past behaviour can be recomputed in more detail and a more accurate prediction can be generated. Generally, current conditions in the simulation are recreated or reset to generate accurate future predictions. In principle, there will always remain uncertainty in future behaviour, however with successive measurements used to calibrate the model these uncertainties are significantly reduced. Multidisciplinary simulations allow strong predictions on future behaviour under defined and hypothetical operating and environmental conditions with feedback from integrated Fitness-For-Service (FFS) assessments to code requirements.

By applying the method according to the invention, traditionally separate activities of Engineering Design and Asset Management can be combined into a multidisciplinary Continuous Design. Changing economic, environmental operating conditions and their effects are seamlessly displayed in a Virtual World that can be explored and manipulated to identify potential opportunities in extending the useful life of the asset. The approach is revolutionary in handling complex asset data in a single source, accessible framework reducing data entropy and optimising data integrity.

Generally, the updated physical data and/or operational data are assigned to a single or a multiple number of parameters of the parametrized model. The updated physical data may be provided using a single or a multiple number of measured parameters associated with the remote infrastructure network. Alternatively, the updated physical data can be generated via simulation. Further, the operational data may include a single or a multiple number of process parameters and/or a single or a multiple number of environmental parameters associated with the remote infrastructure network and it surroundings. Also the process parameters and/or the environmental parameters can be either measured or simulated.

The result or outcome of the above described monitoring process can be used for generating intelligence of the remote infrastructure network operation, e.g. for the purpose of providing information to an operator operating the remote infrastructure network, e.g. in the format of a simulation advice or an engineering advice. Further, the remote infrastructure network can be controlled, directly or indirectly. Accordingly, an efficient and effective managing process can be provided for operating the remote infrastructure network.

The spatially referenced data that is collected for identifying the remote infrastructure network and for building the parametrized model may include geometric data being any type of data that comprises location information, e.g. geometric image data. Said location information can be relative to another object, relative to the center of the earth, also called georeferenced data, or any type of location-indexed data.

The invention also relates to a system.

Further, the invention relates to a computer program product. A computer program product may comprise a set of computer executable instructions stored on a data carrier, such as a flash memory, a CD, a DVD or a cloud storage. The set of computer executable instructions, which allow a programmable computer to carry out the method as defined above, may also be available for downloading from a remote server, for example via the Internet, e.g. as an app. Instead of being run by the operator of the remote infrastructure network, the computer program can be executed in the accessible cloud location and offered back to the operator as a service.

Other advantageous options and embodiments according to the invention are described in the following claims.

By way of example only, embodiments of the present invention will now be described with reference to the accompanying figures in which

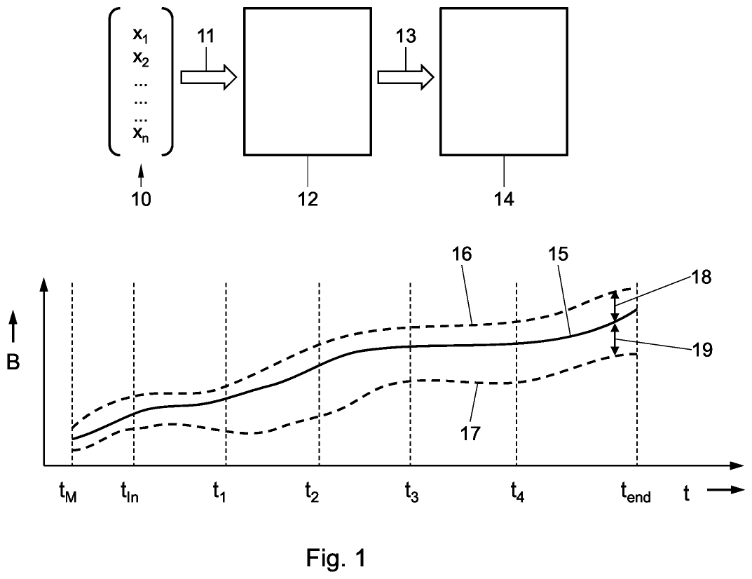

FIG. 1 shows a block diagram and a graph illustrating a process according to the prior art;

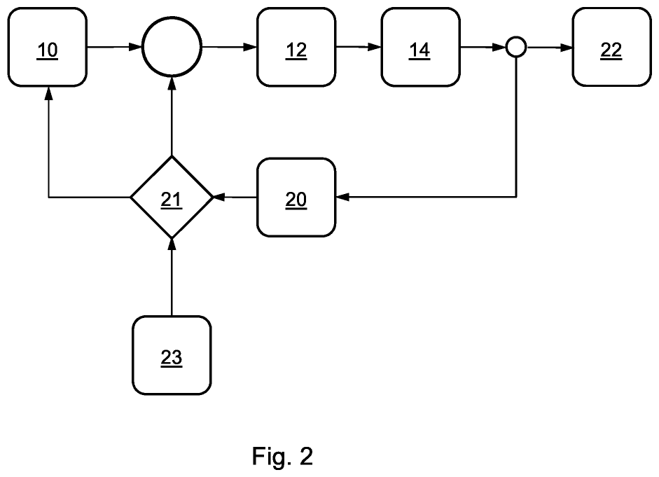

FIG. 2 shows a block diagram illustrating a process according to the invention;

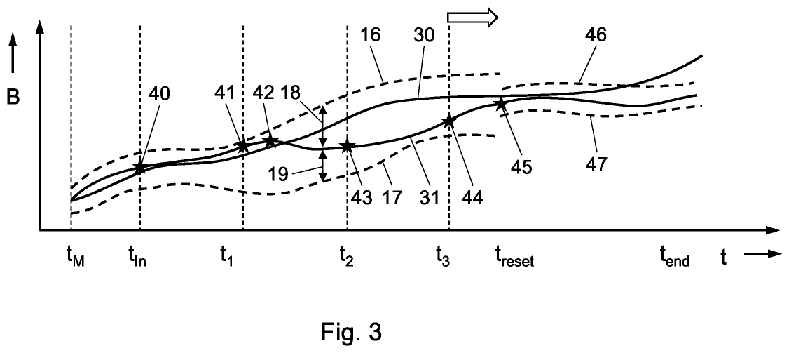

FIG. 3 shows a graph illustrating the process of FIG. 2, and

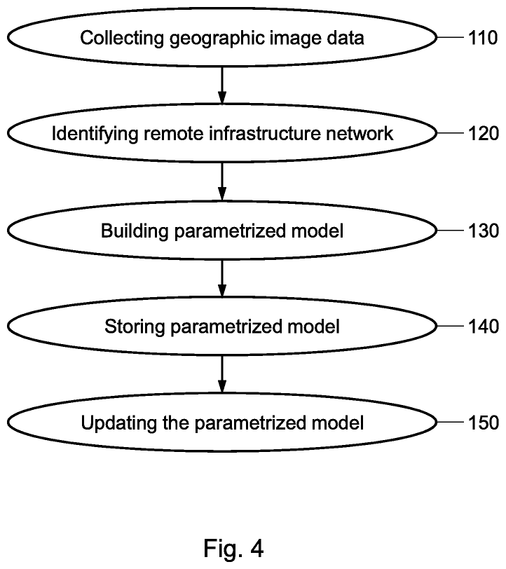

FIG. 4 shows a flow chart of a method according to the invention.

The figures merely illustrate preferred embodiments according to the invention. In the figures, the same reference numbers refer to equal or corresponding parts.

FIG. 1 shows a block diagram and a graph illustrating a process according to the prior art. The block diagram, in the upper part of FIG. 1, includes design data 10 represented as a vector of parameters x₁, x₂, . . . , xₙ, quantifying a remote infrastructure network such as power transmission lines, power distribution lines, substations, subsea pipelines, subsea cables, oil and gas infield assets and other offshore seabed fixed and floating infrastructure, railroads, rail bridges, rail controls and signaling, roads, highways and freeways, traffic and night lights, overpasses and bridges, lane markings and other signals, emergency phones, barriers, embankments, water dams, water pipelines and water pump houses. Such remote infrastructure networks are also called assets. Actual measurements on the asset can be performed. In case of a pipeline the parameters x₁, x₂, . . . , xₙ may include for example bending, torsion, temperature and other parameters.

The vector of parameters x₁, x₂, . . . , xₙ are input, via a first interface 11, into a dynamic model 12 representing the asset. Output parameters of the dynamic model 12 generate, via a second interface 13, a parameter set 14 quantifying a predicted behaviour of the asset such as an actual local bending parameter of a pipeline or a temperature of a water pump.

The graph, in the lower part of FIG. 1, shows a predicted behaviour curve 15 of the asset being a behaviour B function of time t. Generally, the predicted behaviour curve 15 is located between an upper boundary curve 16 and a lower boundary curve 17 defining an upper behaviour uncertainty 18 and a lower behaviour uncertainty 19. The continuous time parameter subsequently includes a manufacture time t_{M}, an installation time t_{In}, observation times t₁, t₂, t₃, t₄ and an End of Life time t_{end}.

FIG. 2 shows a block diagram illustrating a process according to the invention. Again, design data 10 of a remote infrastructure network, also called asset, can be represented by a vector of parameters x₁, x₂, . . . , xₙ. that is input into a dynamic model 12 of the asset.

The dynamic model 12 is a parametrized model of the asset, the model including a spatially referenced model, e.g. a geographic model such as a two-dimensional image model or a three-dimensional image model of the asset. Alternatively, the spatially referenced model can be a 2D or a 3D location-indexed point cloud. The parametrized model 12 is based on physical data of an area containing said asset, and on operational data of said asset. The physical data may include geographic image data, e.g. being two-dimensional or three-dimensional, and have been collected, e.g. via measurements. Further, the asset has been identified in the collected physical data. The operational data may include process parameters and/or environmental parameters.

The parametrized model 12 is stored, e.g. in a memory of a server, preferably remotely accessible such as on a cloud-based server.

Again, the parametrized model 12 generates a parameter set 14 quantifying a predicted or simulated behaviour of the asset. In the shown embodiment, future behaviour 22 of the asset can be derived or calculated from the simulated behaviour parameter set 14, based on the parametrized model 12. In another embodiment, only a simulation of actual behaviour of the asset is generated.

Further, updated physical data and/or operational data associated with the remote infrastructure network are assigned to at least one parameter of the parametrized model 12. This assignment can be, as an example, an input by the user—thereby providing a simulation scenario—or a measurement, as will be further explained in more detail below. As an example, if the remote infrastructure network is a pipeline or another structure, updated physical data such as bending, vibration and/or torsion of the pipeline of the other structure, and/or operational data such as pressure and/or temperature can be assigned to at least one parameter of the model 12, e.g. for the purpose of predicting or simulating a specific behavior of the pipeline or structure, e.g. a local bending of the pipeline or structure, or amplitude and/or orientation of forces occurring in the pipeline or structure. The updated physical data may further include geometry properties and/or dimensions, mass, local material thickness, local material properties such as homogeneity of material and/or change of material such as formation of corrosion layer.

As an example, a measured parameter or a multiple number of measured parameters 20 associated with the asset are assigned to at least one parameter of the parametrized model 12. The measured parameter 20 may represent physical data or environmental data associated with the remote infrastructure network. Examples of environmental data are measurement values of a temperature, a tension, a stress, a pressure, a flow and/or a vibration occurring at or near the asset to be monitored.

Instead of or in addition to assigning a measured parameter, a simulated parameter such as a simulated process parameter associated with the remote infrastructure network can be assigned to the at least one parameter of the parametrized model. Generally, the operational data may include a single or a multiple number of process parameters and/or a single or a multiple number of environmental parameters associated with the remote infrastructure network. By feeding simulated process parameters back to the parametrized model, not only measured parameters but also simulation parameters that the operator may use for simulation purposes can be input to simulate the behavior of the components in the remote infrastructure network. Generally, the updated physical data and/or operational data may include a measured parameter and/or a simulated parameter. Preferably, environmental data corresponds to data measured in the area where the remote infrastructure is located.

The block diagram further includes a decision rhombus 21 forwarding a measured parameter 20, e.g. reflecting physical data and/or environmental parameters directly towards the parametrized model 12 as an observed status of the asset at a time t, while forwarding process parameters 23 to the design data 10 for performing a assignment to the at least one parameter of the parametrized model 12 via the design data 10. In the latter case an enforced change in the design data is included.

By assigning the updated physical data and/or operational data 20 to the parametrized model 12, a transfer function can be used serving as a feedback loop modifying the at least one parameter of the parametrized model 12. As a result, the parametrized model 12 is updated and reflects an actual state of the asset by mapping the updated physical data and/or operational data to the at least one parameter of the model 12, e.g. for the purpose of generating realistic simulated behaviour 14 and/or future behaviour 22. The lifespan of an asset may be simulated using a fatigue calculation using so-called S-N curves and Miners rule. Fatigue is accumulated through an assets life as it experiences fluctuations in stress e.g. due to start-up/shut-down events, i.e. high stress at low frequency, and vibration, i.e. low stress at high frequency.

Preferably, an event signal is generated if a parameter of the parametrized model exceeds a predetermined value. As an example, an event signal is generated if a predefined threshold is reached, e.g. a pipe bending over its design limits or a valve operating at a higher pressure than its design pressure. The event signal may trigger an alert process such as a procedure warning an operator of the remote infrastructure network, e.g. in the format of an advice message, or a controlling process for controlling the remote infrastructure network.

Further, a simulation signal can be generated if the parametrized model is updated by assigning a simulated parameter to at least one parameter of the parametrized model.

Advantageously, the assigning step of the transfer function may include a step of comparing the updated physical data and/or operational data with a database of data such as measured parameters. Further, preferably, at least one parameter of the parametrized model is determined based on the environmental data.

Generally, the parametrized model 12 is based on design data 10 and on operational data associated with the remote infrastructure network.

As indicated above, prior to building a parametrized model 12, spatially referenced data of an area containing at least one remote infrastructure network are collected as physical data, such as geographic image data. Various imaging techniques can be applied, such as aerial photography, LIDAR scans, sonar or radar measurements etc. Then, a remote infrastructure network is identified in said collected physical data. The identification step can be performed including determining a likelihood of the presence of the remote infrastructure network in the collected physical data. Advantageously, network objects can be detected by comparing the image data with library objects.

Then, an effective monitoring system is obtained monitoring an actual state of the remote infrastructure network. As an example, a tailored power distribution control or management solution can be provided that is applicable in the electrical infrastructure sector. In a specific embodiment, asset network models facilitate comprehensive vegetation management, infrastructure condition evaluation and enhanced performance monitoring, thus reducing costs and resources.

Utilizing geographic imaging techniques, observed conditions of electrical assets can be extracted from raw data using automated processing algorithms and fed as input into the parametrized model 12, e.g. in real time or in near real time. Predictive simulation allows asset owners to explore changes in the response of their asset network to hypothetical scenarios, creating a test environment for proposed changes without risking actual infrastructure.

Advantageously, environmental data that is used for the feedback loop 20 can be measured using a single or a multiple number of physical sensors that are located stationary or temporarily near the remote infrastructure network, e.g. using sensors located in the close proximity of the asset, either continuously or interruptently operating, or using district measurement during frequent or infrequent visits to the asset.

Advantageously, the parametrized model of the remote infrastructure network is based on the spatially referenced collected physical data and on operational data such as specific data such as installation data.

As a specific embodiment, geo-referenced point clouds of power lines and attached remote infrastructure networks can be captured using aerial LIDAR and photography. These point clouds represent a physical, geo-referenced state of the infrastructure at the time of capture, optionally under an unknown operational load and optionally with somewhat uncertain installation properties. It is advantageous to an operator to understand the behaviour of this infrastructure under changing/different environmental and operating conditions.

Applying a method according to the invention, forces that occur in the infrastructure network can be identified or at least estimated without any specific additional information from said infrastructure network. Said forces can be estimated with reasonable accuracy also if additional user-specific information, such as information about cable material information or other installation data, has a low level of accuracy or a relatively high level of uncertainty. As an example, based on cable physical properties information such as density, material, diameter, said forces or other operational data may be estimated from the captured spatially referenced data such as infrastructure dimensions and/or geometry, optionally improved by adding user specific information e.g. obtained via a first representation of an asynchronous hysteresis feed-back of information to reduce an uncertainty level.

Now, knowing both cable properties and geometry of the infrastructure network might be sufficient to calculate the forces in the cables e.g. using established mathematical techniques such as a catenary formula. Once information about said forces is obtained simplistic physics can be applied to determine a change in cable geometry from changes in operational loads, for instance, a reduction in load will cool the cable, reducing it's length and leading to an increased clearance height to the ground.

The above described method provides an elegant alternative method to earlier known methods that include local geometry measurements such as measuring a height of a cable above ground which measurement might be superfluous when applying the above described method according to the invention. Instead, according to the described method of the invention, geo-referenced cable locations are determined and optionally combined with some basic user specific information, e.g. installation information of the remote infrastructure network. Further, measurements under the same, similar or different load conditions can be performed. Such method is advantageous for a user thereof since a high degree of accuracy in response of the infrastructure network can be estimated using simple geometry information under changing load conditions without having to perform additional measurements.

As another specific embodiment, geo-referenced point clouds of a same location can be obtained on an annual basis. It may occur that high density, small diameter lines may not be well captured with a minimal number of points captured each year. Additionally, user may not have accurate records of their infrastructure network. In many cases, the location and even number/type of infrastructure that they have may require significant modification to reflect the current status. It is advantageous to the user to maintain updated records of the entirety their infrastructure, particularly due to the remote locations involved.

According to an embodiment of the invention, a process may involve using a combination of statistical methods and multi-year data to accurately identify the location of power lines in sparse point clouds. Knowing that a number of assets exist in a given location is not usually sufficient to automatically capture them, particularly when the prior information may be incorrect. Combining a priori information from a user of said infrastructure network, the previous years modelled infrastructure network, if available, and derived models thereof, viz. infrastructure networks such as poles and power lines, the method may perform an inference matching process to identify differences between the a priori information, in a first data source, and physical data observed from a current geo-referenced point cloud, in a second data source. The identified differences between said first and second data source may be used to correct the customer database and enhance detection results. The results may further be used as multi-year datasets to detect changes in the network and enhance a feature detection process.

Again, user specific information such as installation data may be combined with spatially referenced data that is collected as physical data of an area containing a remote infrastructure network. Especially user specific information may be treated as having a similar uncertainty as the captured physical data observed from a current geo-referenced point cloud. The user specific information and the captured physical data can be fused as two data sources thereby reducing an overall uncertainty in the network model and obtain improved predictions. Advantageously, the fusing process may be automated optionally with some manual intervention in creating the derived models. Further, absolute geo-referenced positioning can be obtained for the entire network, while, usually user specific information may be primarily in relative (i.e. cadastral). It provides value through enhanced visibility of remote infrastructure networks, linking historical records of relational data to a spatial position, and identifying change in the infrastructure network from year to year.

FIG. 3 shows a graph illustrating the process described referring to the above FIG. 2. The graph shows calibrated simulation curves 30, 31 of a remote infrastructure network being a behaviour B function of time t. Again, generally, the calibrated simulation curves 30, 31 are located between an upper boundary curve 16 and a lower boundary curve 17 defining an upper behaviour uncertainty 18 and a lower behaviour uncertainty 19. The continuous time parameter subsequently includes a manufacture time t_{M}, an installation time t_{In}, observation times t₁, t₂, t₃, t₄ and an End of Life time t_{end}. As indicated with stars 40, 41, 43, 44, parameters associated with the asset are monitored at installation time tᵢₙ, and observation times t₁, t₂, t₃. The parametrized model 12 is updated based on the outcome of these observations. Clearly, the unmodified simulation curve 30 deviates form the calibrated simulation curve 31 that is based on the above-mentioned observations. Further, the graph illustrates time instants wherein the design data 10 are modified upon request of an operator, indicated with stars 42, 45. Modified design data 10 associated with updated process data also generate an update of the parametrized model 12 resulting in modified simulation curves. The graph also illustrates a future continuation of the calibrated simulation curves being predicted behaviour curves 30, 31, after a time instant tᵣₑₛₑₜ coinciding with the last star 44 when the design data 10 are modified. As shown, the predicted behaviour curve 31 of the calibrated model remains between stricter upper and lower boundary curves 46, 47, enabling a continuous design process of the asset.

FIG. 4 shows a flow chart of an embodiment of a method 100 according to the invention. The method 100 is used for monitoring remote infrastructure networks, and comprises a step of collecting 110 spatially referenced data as physical data of an area containing a remote infrastructure network, a step of identifying 120 the remote infrastructure network in the collected physical data, a step of building 130 a parametrized model of the remote infrastructure network based on the geographic image data and on operational data, the parametrized model including a spatially referenced model of said remote infrastructure network, a step of storing 140 the parametrized model, and a step of updating 150 the parametrized model by assigning updated physical data and/or operational data associated with the remote infrastructure network to at least one parameter of the parametrized model.

The method of monitoring remote infrastructure networks can be facilitated using dedicated hardware structures, such as computer servers, e.g. a cloud-based server. Otherwise, the method can also at least partially be performed using a computer program product comprising instructions for causing a processor of a computer system to performing the monitoring activities. All (sub)steps can in principle be performed on a single processor. However, it is noted that at least one step can be performed on a separate processor. A processor can be loaded with a specific software module. Dedicated software modules can be provided, e.g. from the Internet.

The invention also relates to a system for monitoring remote infrastructure networks, comprising a server provided with a processor and a memory arranged for performing the above described steps. The monitoring system may include a sensor for measuring physical data to be assigned to the at least one parameter of the parametrized model. Alternatively, the system is arranged to receive such measured parameter data. Also, the system may comprise an actuator setting a parameter of the remote infrastructure network, such as a valve controlling a current in a pipeline or another movable element in or on said network for interacting with a process in said remote infrastructure network. Preferably, the server is remotely accessible, e.g. using a web-based structure.

According to the invention an interactive virtual system may be obtained facilitating a Continuous Design process, comprising an automated simulation model based on remote observation, wherein assets are managed and controlled remotely through regular or irregular observation data. Further, automated algorithms can be used to obtain information on the current status of the asset, optionally followed by modelling of past, present and future asset behaviour to increase the value of the asset as well as simulation of hypothetical scenarios.

Advantageously, a parametric design space may be provided containing spatial and temporal, hypothetical, i.e. assumed, and actual measured or defined data, wherein feedback loops reduce uncertainty in the past assumed data through successive calibration to measured and/or defined data.

Preferably, the above-mentioned feedback loop based on observation data comprises an integrated multidisciplinary engineering calculation for fitness for service meeting relevant code requirements.

Further, future behaviour to requested changes can be predicted through simulation with integrated multidisciplinary engineering calculation according to relevant code requirements.

Optionally, inspection, repair and/or maintenance activities can be coordinated based on current and simulated asset requirements and/or behaviour.

The invention is not restricted to the embodiments described herein. It will be understood that many variants are possible.

These and other embodiments will be apparent for the person skilled in the art and are considered to fall within the scope of the invention as defined in the following claims. For the purpose of clarity and a concise description features are described herein as part of the same or separate embodiments. However, it will be appreciated that the scope of the invention may include embodiments having combinations of all or some of the features described.

1. A method for monitoring remote infrastructure networks, the method comprising:
collecting spatially referenced data as physical data of an area containing a remote infrastructure network;
identifying the remote infrastructure network in the collected physical data;
building a parametrized model of the remote infrastructure network based on the physical data and on operational data, the parametrized model including a spatially referenced model of the remote infrastructure network;
storing the parametrized model; and
updating the parametrized model by assigning updated physical data and/or operational data associated with the remote infrastructure network to at least one parameter of the parametrized model.

2. The method according to claim 1, further comprising transmitting data of the parametrized model to a visualization station for providing a graphical representation of the parametrized model.

3. The method according to claim 1, wherein
the operational data include process parameters and/or environmental parameters.

4. The method according to claim 1, wherein the updated physical data and/or operational data include a measured parameter and/or a simulated parameter.

5. The method according to claim 1, wherein the operational data includes user specific data from the remote infrastructure network.

6. The method according to claim 1, wherein an event signal is generated when a parameter of the parametrized model exceeds a predetermined value.

7. The method according to claim 1, wherein a simulation signal is generated when the parametrized model is updated by assigning a simulated parameter to at least one parameter of the parametrized model.

8. The method according to claim 1, wherein the updated physical data and/or operational data are assigned using a transfer function, the transfer function serving as a feedback loop modifying at least one parameter of the parametrized model.

9. The method according to claim 1, wherein the spatially referenced data includes geographic data.

10. The method according to claim 9, wherein the geographic data is three-dimensional and/or wherein the spatially referenced model of the remote infrastructure network is a three-dimensional model.

11. The method according to claim 1, wherein the parametrized model is remotely accessible.

12. The method according to claim 1, further comprising determining a likelihood of the presence of the remote infrastructure network in the collected physical data.

13. The method according to claim 1, wherein the operational data includes environmental data, the environmental data are measured using a sensor located stationary or temporarily near the remote infrastructure network.

14. The method according to claim 1, wherein the operational data includes environmental data, the environmental data include a measurement value of a temperature, a pressure, a flow and/or a vibration.

15. The method according to claim 1, further comprising comparing the updated physical data and/or operational data with a database of data.

16. The method according to claim 1, further comprising calculating future behavior of the remote infrastructure network based on the parametrized model.

17. The method according to claim 1, wherein the operational data includes environmental data, the environmental data corresponds to data measured in the area where the remote infrastructure network is located.

18. A system for monitoring remote infrastructure networks, comprising a server with at least one processor and at least one non-transitory memory, the at least one non-transitory memory storing instructions which when executed by the at least one processor causes the server to:
collect spatially referenced data as physical data of an area containing a remote infrastructure network;
identify the remote infrastructure network in the collected physical data;
build a parametrized model of the remote infrastructure network based on the physical data and on operational data, the parametrized model including a spatially referenced model of the remote infrastructure network;
store the parametrized model; and
update the parametrized model by assigning updated physical data and/or operational data associated with the remote infrastructure network to at least one parameter of the parametrized model.

19. The monitoring system according to claim 18, wherein the server is cloud-based.

20. The monitoring system according to claim 18, further comprising a sensor for measuring physical data to be assigned to at least one parameter of the parametrized model.

21. The monitoring system according to claim 18, further comprising an actuator setting a parameter of the remote infrastructure network.

22. A non-transitory computer readable medium storing instructions which when executed by at least one processor causes the at least one processor to:
collect spatially referenced data as physical data of an area containing a remote infrastructure network;
identify the remote infrastructure network in the collected physical data;
build a parametrized model of the remote infrastructure network based on the physical data and on operational data, the parametrized model including a spatially referenced model of the remote infrastructure network;
store the parametrized model, and
update the parametrized model by assigning updated physical data and/or operational data associated with the remote infrastructure network to at least one parameter of the parametrized model.
